(19) United States
(12) Patent Application Publication
(10) Pub. No.: US 2023/0267320 A1
(43) Pub. Date: Aug. 24, 2023

(54) FERROELECTRIC FIELD EFFECT TRANSISTOR, NEURAL NETWORK APPARATUS, AND ELECTRONIC DEVICE

(71) Applicant: Samsung Electronics Co., Ltd., Suwon-si (KR)

(72) Inventors: Taehwan MOON, Suwon-si (KR); Jinseong Heo, Suwon-si (KR); Seunggeol Nam, Suwon-si (KR); Hagyoul Bae, Suwon-si (KR); Hyunjae Lee, Suwon-si (KR)

(73) Assignee: Samsung Electronics Co., Ltd., Suwon-si (KR)

(21) Appl. No.: 18/168,681

(22) Filed: Feb. 14, 2023

(30) Foreign Application Priority Data
Feb. 18, 2022 (KR) 10-2022-0021735

(51) Int. Cl. G06N 3/063; H10B 51/30; H01L 29/06; H01L 29/423; H01L 29/49; H01L 29/51; H01L 29/78; H01L 29/775; G11C 11/22; G11C 11/54

(52) U.S. Cl. CPC G06N 3/063; H10B 51/30; H01L 29/0673; H01L 29/42392; H01L 29/4966; H01L 29/516; H01L 29/78391; H01L 29/7851; H01L 29/775; G11C 11/223; G11C 11/2255; G11C 11/2257; G11C 11/54

(57) ABSTRACT

A ferroelectric field effect transistor includes: a source; a drain; a first channel connected to and between the source and the drain; a second channel connected to and between the source and the drain and spaced apart from the first channel; a ferroelectric layer covering the first channel and the second channel; a first gate layer disposed on the ferroelectric layer in correspondence with the first channel; a second gate layer disposed on the ferroelectric layer in correspondence with the second channel; and a gate wiring electrically connecting the first gate layer to the second gate layer, wherein the first gate layer includes a first metallic material having a first work function, and the second gate layer includes a second metallic material having a second work function, wherein the second work function is different from the first work function.

### CROSS-REFERENCE TO RELATED APPLICATION

This application is based on and claims priority under 35 U.S.C. § 119 to Korean Patent Application No. 10-2022-0021735, filed on Feb. 18, 2022 in the Korean Intellectual Property Office, the disclosure of which is incorporated by reference herein in its entirety.

### BACKGROUND

### 1. Field

The disclosure relates to a ferroelectric field effect transistor, a neural network apparatus including the ferroelectric field effect transistor, and an electronic device including the neural network apparatus.

### 2. Description of the Related Art

There has been a growing interest in a neuromorphic processor performing neural network operations. The neuromorphic processor may be used as a neural network apparatus for driving various kinds of neural networks, such as a Convolutional Neural Network (CNN), a Recurrent Neural Network (RNN), a Feedforward Neural Network (FNN), etc., and may be used in the fields which involve data classification, image recognition, autonomous control, speak recognition, etc.

The neuromorphic processor may include (or be connected to) a plurality of memory cells for storing weights. A memory cell may be implemented by various elements, and recently, to reduce an area of the memory cell and power consumption, a non-volatile memory with a simple structure has been suggested as a memory cell of the neuromorphic processor.

### SUMMARY

Provided are ferroelectric field effect transistors having a linear response characteristic with respect to an applied voltage.

Provided are neural network apparatuses including the ferroelectric field effect transistors.

Provided are electronic devices including the neural network apparatuses.

Additional aspects will be set forth in part in the description which follows and, in part, will be apparent from the description, or may be learned by practice of the presented embodiments of the disclosure.

According to an aspect of at least one embodiment, a ferroelectric field effect transistor includes: a source; a drain; a first channel connected to and between the source and the drain; a second channel connected to and between the source and the drain and disposed apart from the first channel; a ferroelectric layer at least partially covering the first channel and the second channel; a first gate layer on the ferroelectric layer, the first gate layer at least partially covering the first channel; a second gate layer on the ferroelectric layer, the second gate layer at least partially covering the second channel; and a gate wiring electrically connected to the first gate layer and the second gate layer, wherein the first gate layer includes a first metallic material having a first work function, the second gate layer includes a second metallic material having a second work function, the second work function is different from the first work function.

The first channel and the second channel may be electrically connected in parallel.

at least one of the first metallic material or the second metallic material may include at least one of TiN, TiAlN, TaN, Co, WN, NbN, W, Mo, or Pt.

The ferroelectric layer may include an oxide of at least one of Si, Al, Hf, or Zr and a dopant, wherein the dopant is at least one of Si, Al, Y, La, Gd, Mg, Ca, Sr, Ba, Ti, Zr, Hf, and N, MgZnO, AlScN, BaTiO₃, Pb(Zr,Ti)O₃, SrBiTaO₇, or polyvinylidene fluoride (PVDF).

The ferroelectric field effect transistor may further include a substrate, and the source, the drain, the first channel, and the second channel may protrude from an upper surface of the substrate in a first direction.

The first channel and the second channel may extend in a second direction perpendicular to the first direction.

The first channel and the second channel may be disposed apart from each other in a third direction perpendicular to the first direction and the second direction.

The ferroelectric field effect transistor may further include a substrate, the source and the drain may protrude from the upper surface of the substrate in the first direction, and the first channel and the second channel may be spaced apart from the upper surface of the substrate in the first direction.

The first channel and the second channel may extend in the second direction perpendicular to the first direction, and the first channel and the second channel may be spaced apart from each other in at least one of the first direction or in the third direction perpendicular to the first direction and the second direction.

The ferroelectric layer may include a first ferroelectric layer surrounding the first channel and a second ferroelectric layer surrounding the second channel.

The first gate layer may surround the first ferroelectric layer, and the second gate layer may surround the second ferroelectric layer.

The ferroelectric field effect transistor may further include a third gate layer on the ferroelectric layer, the third gate layer at least partially covering the third channel and including a third metallic material having a third work function, the third work function different from the first work function and the second work function, and the gate wiring electrically connects the first gate layer, the second gate layer, and the third gate layer to each other.

A value obtained by dividing a greater work function, between the first work function of the first gate layer and the second work function of the second gate layer, by the other work function of the first gate layer or the second gate layer, is between 5% to 100%. According to an aspect of at least one embodiment, a neural network apparatus includes: a plurality of word lines; a plurality of bit lines; a plurality of input lines; a plurality of output lines; and a plurality of synaptic elements at intersection points where the plurality of word lines and the plurality of bit lines intersect with each other, and electrically connecting a corresponding word line of the plurality of word lines, a corresponding bit line of the plurality of bit lines, a corresponding input line of the plurality of input lines, and a corresponding output line of the plurality of output lines, wherein each of the plurality of synaptic elements includes an access transistor and a ferroelectric field effect transistor, wherein the ferroelectric field effect transistor includes a source, a drain, a first channel connected to and between the source and the drain, a second channel connected to and between the source and the drain and spaced apart from the first channel, a ferroelectric layer at least partially covering the first channel and the second channel, a first gate layer on the ferroelectric layer, the first gate layer at least partially covering the first channel, a second gate layer on the ferroelectric layer, the second gate layer at least partially covering the second channel, and a gate wiring electrically connecting the first gate layer to the second gate layer, wherein the first gate layer includes a first metallic material having a first work function, the second gate layer includes a second metallic material having a second work function, and the second work function is different from the first work function.

A gate of the access transistor may be electrically connected to a corresponding word line of the plurality of word lines, a source of the access transistor may be electrically connected to a corresponding bit line of the plurality of bit lines, a drain of the access transistor may be electrically connected to the gate wiring of the ferroelectric field effect transistor, the source of the ferroelectric field effect transistor may be electrically connected to the corresponding input line, and the drain of the ferroelectric field effect transistor may be electrically connected to the corresponding output line.

The neural network apparatus may further include: a word line driver configured to provide a signal to the plurality of word lines; a bit line driver configured to provide a signal to the plurality of bit lines; an input circuit configured to provide a signal to the plurality of input lines; and an output circuit configured to provide a signal from the plurality of output lines.

During a learning operation of the neural network apparatus, the word line driver may be configured to sequentially apply a turn-on signal to the plurality of word lines, and the bit line driver may be configured to apply a weight signal to the plurality of bit lines.

During an inference operation of the neural network apparatus, the word line driver may be configured to apply a turn-on signal to the plurality of word lines, and the bit line driver may be configured to apply a read voltage to the plurality of bit lines.

According to an aspect of at least one embodiment, an electronic device includes: a neural network apparatus configured as described above; a memory including computer-executable instructions; and a processor configured to control functions of the neural network apparatus by executing the computer-executable instructions stored in the memory such that the neural network apparatus performs a neural network operation based on input data received from the processor and generates an information signal corresponding to the input data, based on a result of the neural network operation.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a structure of a ferroelectric field effect transistor according to at least one embodiment;

FIG. 2 is a cross-sectional view illustrating a channel and a gate structure of the ferroelectric field effect transistor of FIG. 1;

FIG. 3 is a cross-sectional view illustrating a channel and a gate structure of a ferroelectric field effect transistor according to at least one embodiment;

FIG. 4 is a cross-sectional view illustrating a channel and a gate structure of a ferroelectric field effect transistor according to at least one embodiment;

FIG. 5 is a graph showing switching characteristics of a ferroelectric field effect transistor and a principle by which the ferroelectric field effect transistor has linear state change characteristics;

FIG. 6 is a graph showing an example of voltage-current characteristics of a ferroelectric field effect transistor according to at least one embodiment;

FIG. 7 shows a potentiation and depression (PD) curve exhibiting a principle by which a ferroelectric field effect transistor has linear state change characteristics, according to at least one embodiment;

FIG. 8 is a perspective view schematically illustrating a structure of a ferroelectric field effect transistor according to at least one embodiment;

FIG. 9 is a cross-sectional view illustrating a channel and a gate structure of the ferroelectric field effect transistor of FIG. 8;

FIG. 10 is a block diagram schematically illustrating a configuration of a neural network apparatus according to at least one embodiment;

FIG. 11 is a schematic view of a unit synaptic element of the neural network apparatus of FIG. 10;

FIG. 12 is a block diagram schematically illustrating a configuration of an electronic device including a neural network apparatus;

FIG. 13 is a view for comparing a PD characteristic curve of a single ferroelectric memory with a PD characteristic curve of a memory cell according to at least one embodiment;

FIG. 14 is a view for describing an architecture of a neural network according to at least one embodiment. FIG. 15 is a view for describing an arithmetic operation performed in a neural network according to at least one embodiment; and

FIG. 15 is a view for describing an arithmetic operation performed in a neural network according to at least one embodiment.

### DETAILED DESCRIPTION

Reference will now be made in detail to some example embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, referring to the accompanying drawings, a ferroelectric entire field effect transistor, a neural network apparatus, and an electronic device will be described in detail. In the drawings, like reference numerals denote like components, and sizes of components may be exaggerated for clarity and convenience of explanation. Meanwhile, embodiments described below are provided merely as an example, and various modifications may be made from the embodiments.

It will be understood that when a component is referred to as being “on” another component or on an “upper portion” of another component, the component can be directly on the other component or over the other component in a non-contact manner. It will be understood that the spatially relative terms are intended to encompass different orientations of the device in use or operation in addition to the orientation depicted in the figures. For example, if the device in the figures is otherwise oriented (e.g., rotated 90 degrees or at other orientations), the spatially relative descriptors used herein are to be interpreted accordingly. As used herein, the singular forms “a,” “an” and “the” are intended to include the plural forms as well, unless the context clearly indicates otherwise. When a portion “includes” a component, another component may be further included, rather than excluding the existence of the other component, unless otherwise described.

When the terms “about” or “substantially” are used in this specification in connection with a numerical value, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values. The operations of all methods described herein can be performed in any suitable order unless otherwise indicated herein or otherwise clearly contradicted by context, and embodiments are not limited to the described order of the operations.

In addition, the terms “. . . portion,” “module,” etc., described in the specification refer to a unit for processing at least one function or operation, which can be implemented by processing circuitry such as hardware, software, and/or a combination of a hardware and a software. For example, the processing circuitry more specifically may include (and/or be included in), but is not limited to, a processor, Central Processing Unit (CPU), a controller, an arithmetic logic unit (ALU), a digital signal processor, a microcomputer, a field programmable gate array (FPGA), a System-on-Chip (SoC), a programmable logic unit, a microprocessor, application-specific integrated circuit (ASIC), semiconductor elements in an integrated circuit, circuits enrolled as an intellectual property (IP), etc.

The connecting lines or connectors shown in the various figures presented are intended to represent example functional relationships and/or physical and/or circuital couplings between the various components, and thus it should be noted that many alternative or additional functional relationships, physical connections or circuital connections may be present in a practical device.

The use of any and all examples, or exemplary languages provided herein, is intended merely to better illuminate embodiments and does not pose a limitation on the scope of embodiments unless otherwise claimed.

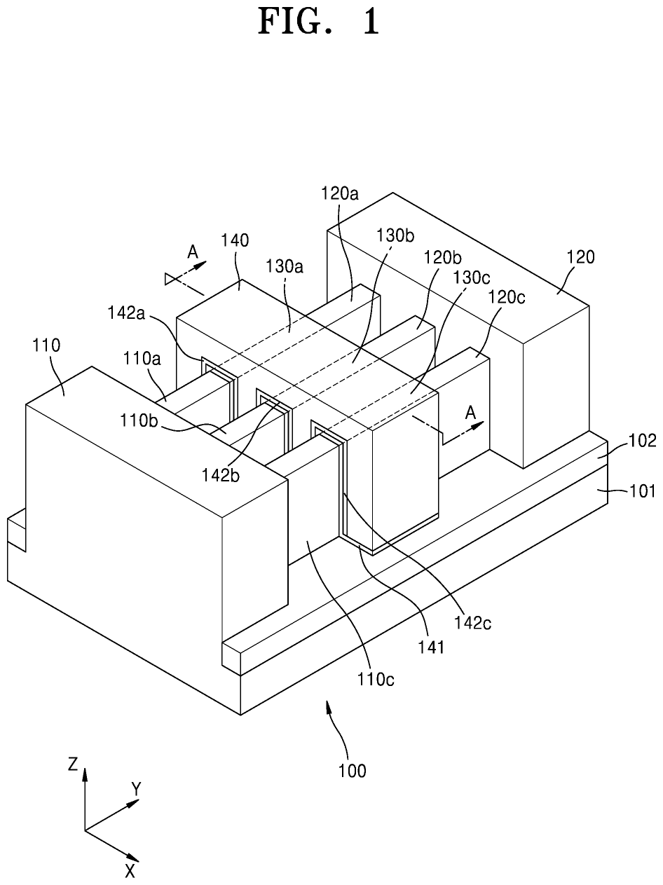

FIG. 1 is a perspective view schematically illustrating a structure of a ferroelectric field effect transistor according to at least one embodiment. Referring to FIG. 1, a ferroelectric field effect transistor 100 may include a source 110, a drain 120, a first channel 130a connected to and between the source 110 and the drain 120, a second channel 130b connected to and between the source 110 and the drain 120, a third channel 130c connected to and between the source 110 and the drain 120, a ferroelectric layer 141 covering the first to third channels 130a, 130b, and 130c, a first gate layer 142a disposed on the ferroelectric layer 141 to cover the first channel 130a, a second gate layer 142b disposed on the ferroelectric layer 141 to cover the second channel 130b, a third gate layer 142c disposed on the ferroelectric layer 141 to cover the third channel 130c, and a gate wiring 140 electrically connecting the first to third gate layers 142a, 142b, and 142c to each other. Although FIG. 1 illustrates that the gate wiring 140 covers all of the first to third gate layers 142a, 142b, and 142c, the gate wiring 140 may include other and/or additional components electrically connecting the first to third gate layers 142a, 142b, and 142c to each other. The gate wiring 140 may form a gate electrode of the ferroelectric field effect transistor 100 together with the first to third gate layers 142a, 142b, and 142c.

The ferroelectric field effect transistor 100 may further include a substrate 101 and an isolator 102 disposed on an upper surface of the substrate 101. The substrate 101 may include a semiconductor material. The source 110 and the drain 120 may be disposed to protrude from the upper surface of the substrate 101 in a Z (or first) direction. The first to third channels 130a, 130b, and 130c may protrude from the upper surface of the substrate 101 in the Z direction and have a shape of a bar extending in a Y (or second) direction. For example, one end of each of the first to third channels 130a, 130b, and 130c may be in contact with the source 110 and the other ends of the first to third channels 130a, 130b, and 130c may be in contact with the drain 120. The source 110 may include a first extension 110a, a second extension 110b, and a third extension 110c, which have the same bar shape as the first to third channels 130a, 130b, and 130c and extend in the Y direction to be connected to the first to third channels 130a, 130b, and 130c, respectively. The drain 120 may include a first extension 120a, a second extension 120b, and a third extension 120c, which have the same bar shape as the first to third channels 130a, 130b, and 130c and extend in the Y direction to be connected to the first to third channels 130a, 130b, and 130c, respectively. In at least one embodiment, the source extension, the channel, and the drain extension may be formed in the same process and/or form a contiguous bar. For example, source extension (e.g., 110a, the channel (e.g., 130a), and the drain extension (e.g., 120a) may be a contiguous bar extending in the Y direction, and the first channel 130a may be a region of the contiguous bar under the gate wiring 140. The source extension, the channel, and/or the drain extension may include the same or different material. For example, in at least one embodiment, the source extension, the channel, and/or the drain extension may include the same base material (e.g., a semiconductor material) and/or different dopants. The ferroelectric field effect transistor 100 having the aforementioned structure may be, for example, a Fin Field Effect Transistor (FinFET).

The isolator 102 may include an insulating dielectric material and may be disposed to extend in the Y direction (and/or a third (or X) direction) along both sides of the source 110, the first to third channels 130a, 130b, and 130c, the gate wiring 140, and the drain 120 on the upper surface of the substrate 101. Moreover, the isolator 102 may be disposed between the first to third channels 130a, 130b, and 130c, between the first to third extensions 110a, 110b, and 110c of the source 110, and between the first to third extensions 120a, 120b, and 120c of the drain 120. The isolator 102 may electrically isolate adjacent ferroelectric field effect transistors.

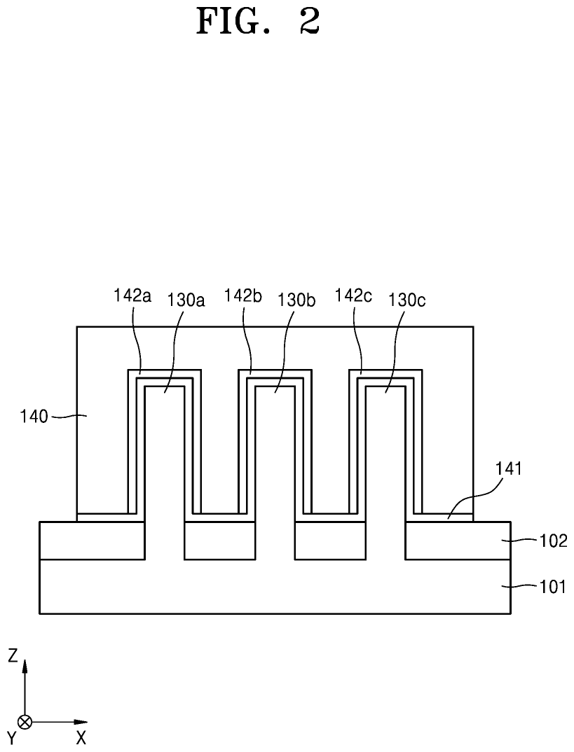

FIG. 2 is a cross-sectional view illustrating a channel and a gate structure of the ferroelectric field effect transistor 100 of FIG. 1, and in particular, FIG. 2 schematically illustrates a cross-section of the ferroelectric field effect transistor 100, taken along the line A-A′ of FIG. 1. Referring to FIG. 2, the first to third channels 130a, 130b, and 130c may each protrude and extend from the substrate 101 in the Z direction and may be spaced apart from each other in the X direction. The isolator 102 may be disposed between adjacent first to third channels 130a, 130b, and 130c.

The ferroelectric layer 141 may be formed as a single layer covering all of the first to third channels 130a, 130b, and 130c. For example, the ferroelectric layer 141 may cover both sides and upper surfaces of the first to third channels 130a, 130b, and 130c and may extend between the first to third channels 130a, 130b, and 130c. The ferroelectric layer 141 may include a ferroelectric including, e.g., at least one of an oxide of Si, Al, Hf, Zr, and/or the like doped with at least one dopant selected from Si, Al, Y, La, Gd, Mg, Ca, Sr, Ba, Ti, Zr, Hf, and N, MgZnO, AlScN, BaTiO₃, Pb(Zr,Ti)O₃, SrBiTaO₇, PVDF, and/or the like. A ferroelectric may refer to a material having ferroelectricity to maintain spontaneous polarization by aligning internal electric dipole moments with no external electric field applied from the outside. A conductivity between the source 110 and the drain 120 may vary depending on a polarization direction of the ferroelectric layer 141. Moreover, a threshold voltage of the ferroelectric field effect transistor 100 may be changed according to the polarization direction of the ferroelectric layer 141. The ferroelectric field effect transistor 100 may be used in, for example, a non-volatile memory cell of a synaptic element for storing weights of a neuromorphic processor.

The first to third gate layers 142a, 142b, and 142c may be disposed on the ferroelectric layer 141 to respectively cover (e.g., at least partially surround) the first to third channels 130a, 130b, and 130c respectively corresponding to the first to third gate layers 142a, 142b, and 142c. For example, the first gate layer 142a may be disposed on the ferroelectric layer 141 to surround both sides and an upper surface of the first channel 130a; the second gate layer 142b may be disposed on the ferroelectric layer 141 to surround both sides and an upper surface of the second channel 130b; and/or the third gate layer 142c may be disposed on the ferroelectric layer 141 to surround both sides and an upper surface of the third channel 130c. The first to third gate layers 142a, 142b, and 142c may each include metallic materials having different work functions. For example, the first gate layer 142a may include a metallic material having a first work function, the second gate layer 142b may include a metallic material having a second work function, and the third gate layer 142c may include a metallic material having a third work function, wherein the second work function is different from the first work function, and the third work function is different from the first and second work functions. The first to third gate layers 142a, 142b, and 142c may include at least one metallic material selected from, for example, TiN, TiAlN, TaN, Co, WN, NbN, W, Mo, and/or Pt.

The gate wiring 140 may be disposed to cover all of the first to third gate layers 142a, 142b, and 142c. Accordingly, the first to third gate layers 142a, 142b, and 142c may be electrically connected to each other. In other words, the same gate voltage may be simultaneously applied to the first to third gate layers 142a, 142b, and 142c. However, as the first to third gate layers 142a, 142b, and 142c have different work functions, a voltage applied to the ferroelectric layer 141 covering the first channel 130a, a voltage applied to the ferroelectric layer 141 covering the second channel 130b, and a voltage applied to the ferroelectric layer 141 covering the third channel 130c may be different from each other. As a result, even when the first to third channels 130a, 130b, and 130c have the same structure and material, channel conductivity may change differently in each of the first to third channels 130a, 130b, and 130c. In terms of the foregoing, the ferroelectric field effect transistor 100 illustrated in FIG. 1 may include the first to third channels 130a, 130b, and 130c, which are different from each other and electrically connected in parallel to and between the source 110 and the drain 120.

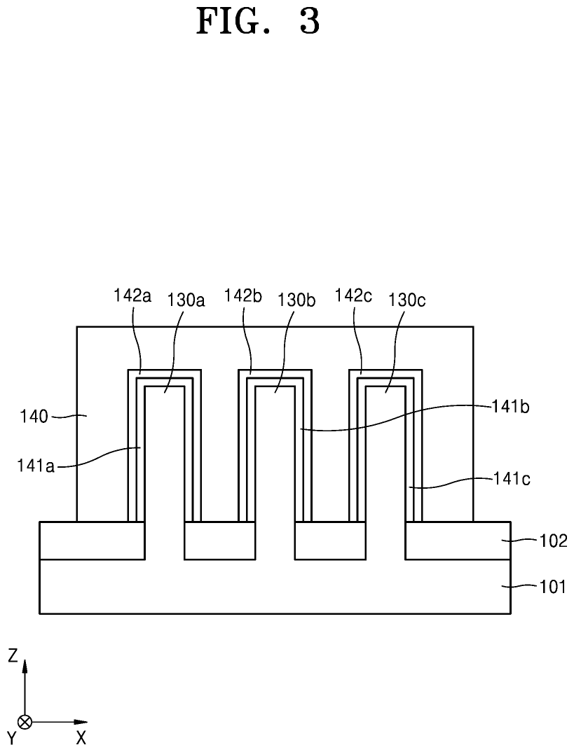

FIG. 3 is a cross-sectional view illustrating a channel and a gate structure of a ferroelectric field effect transistor according to at least one embodiment. Although FIG. 2 illustrates that one ferroelectric layer 141 is disposed to cover all of the first to third channels 130a, 130b, and 130c, a separate individual ferroelectric layer may be disposed on each of the first to third channels 130a, 130b, and 130c. Referring to FIG. 3, the ferroelectric field effect transistor may include a first ferroelectric layer 141a covering both sides and an upper surface of the first channel 130a, a second ferroelectric layer 141b covering both sides and an upper surface of the second channel 130b, and a third ferroelectric layer 141c covering both sides and an upper surface of the third channel 130c. The first to third ferroelectric layers 141a, 141b, and 141c may include the same ferroelectric material and/or different ferroelectric materials.

FIGS. 1 to 3 each illustrate an example of a ferroelectric field effect transistor formed by using the substrate 101 including a bulk semiconductor. In this case, the first to third channels 130a, 130b, and 130c may be an area of an upper portion of the bulk semiconductor left after the upper portion of the bulk semiconductor substrate is etched. The ferroelectric field effect transistor may be formed on a silicon on insulator (SOI) substrate instead of the bulk semiconductor substrate.

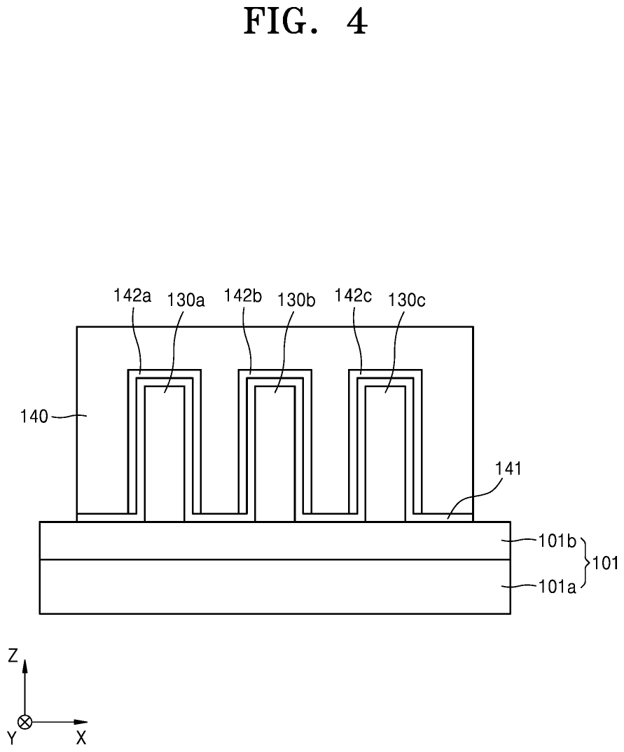

FIG. 4 is a cross-sectional view illustrating a channel and a gate structure of a ferroelectric field effect transistor according to at least one embodiment. Referring to FIG. 4, the substrate 101 may be an SOI substrate including a silicon layer 101a and an insulating layer 101b. In this case, the first to third channels 130a, 130b, and 130c may be formed by depositing them on the insulating layer 101b of the substrate 101.

FIGS. 1 to 4 illustrate that the ferroelectric field effect transistor 100 includes three channels (e.g., the first to third channels 130a, 130b, and 130c) connected in parallel to and between the source 110 and the drain 120; however, this description is provided merely as an example, and the number of channels is not limited to three. For example, a ferroelectric field effect transistor may include two channels connected in parallel, and/or four or more channels connected in parallel.

In general, a conductivity of each channel in a ferroelectric field effect transistor may be changed drastically near a coercive voltage. In other words, the conductivity of each channel may change in a non-linear manner. However, in case of a ferroelectric field effect transistor including a plurality of channels connected to each to other in parallel, according to some embodiments, even when a gate voltage has a value near a coercive voltage for one channel, in another channel connected in parallel to the channel, a change of the channel conductivity may be relatively slow. As a result, an average channel conductivity for multiple channels may be changed linearly.

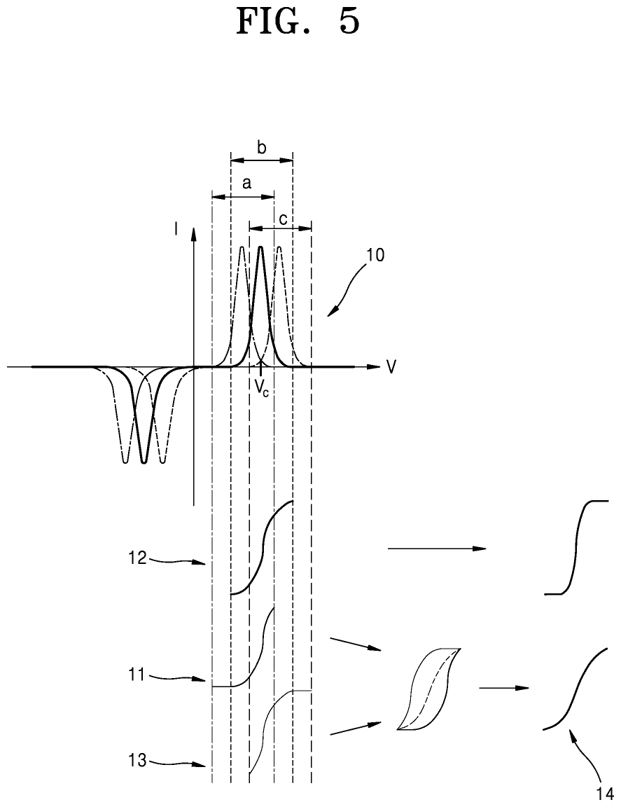

FIGS. 5 to 7 are diagrams to explain a principle by which a ferroelectric field effect transistor has linear state change characteristics.

FIG. 5 is a graph showing switching characteristics of a ferroelectric field effect transistor and a principle by which the ferroelectric field effect transistor has linear state change characteristics. In a voltage-current characteristic curve 10 representing the switching characteristics of the ferroelectric field effect transistor shown in FIG. 5, a current may refer to a displacement current between a gate electrode and a substrate. Referring to a positive voltage part of the voltage-current characteristic curve 10, when a gate voltage gradually increases from 0, a conductivity of the first to third channels 130a, 130b, and 130c may drastically change in each of different gate voltage ranges. This is because a voltage applied to the ferroelectric layer 141 may be different in the first to third channels 130a, 130b, and 130c due to different work functions of the first to third gate layers 142a, 142b, and 142c even when the first to third channels 130a, 130b, and 130c have the same coercive voltage Vc. As a result, a gate voltage to apply the coercive voltage to the ferroelectric layer 141 may vary in each of the first to third channels 130a, 130b, and 130c.

For example, as for the first channel 130a, polarization switching of the ferroelectric may occur in a gate voltage range corresponding to the section a, and channel conductivity may be changed drastically in the section a. As for the second channel 130b, polarization switching of the ferroelectric may occur in a gate voltage range corresponding to the section b, and channel conductivity may be changed drastically in the section b. As for the third channel 130c, polarization switching of the ferroelectric may occur in a gate voltage range corresponding to the section c, and channel conductivity may be changed drastically in the section c.

The conductivity change of the first channel 130a in correspondence with the section a of the voltage-current characteristic curve 10 may be represented by a first Potentiation and Depression (PD) curve 11, the conductivity change of the second channel 130b in correspondence with the section b of the voltage-current characteristic curve 10 may be represented by a second PD curve 12, and the conductivity change of the third channel 130c in correspondence with the section c of the voltage-current characteristic curve 10 may be represented by a third PD curve 13. Each of the first PD curve 11, the second PD curve 12, and the third PD curve 13 may have non-linear characteristics with respect to the gate voltage. When comparing a composite PD curve 15, which is a result of normalizing and combining the first PD curve 11 and the third PD curve 13, with the second PD curve 12, it is understood that the composite PD curve 15 is more linear with respect to the gate voltage change. The composite PD curve 15 may correspond to a composite conductivity of the first channel 130a and the third channel 130c connected in parallel. Accordingly, by connecting in parallel the first channel 130a and the third channel 130c having different gate voltage ranges for polarization switching, a more linear conductivity may be obtained with respect to the gate voltage change, and the composite conductivity of the first to third channels 130a, 130b, and 130c connected in parallel may have more linear characteristics.

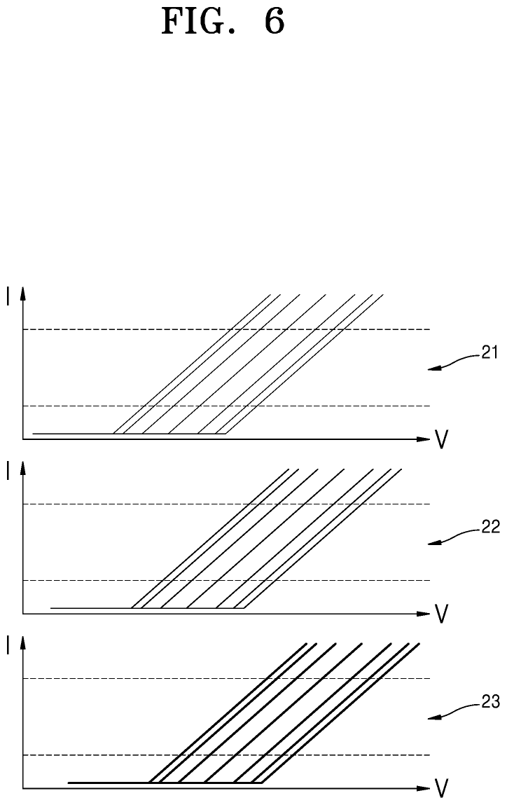

FIG. 6 is a graph showing an example of voltage-current characteristics of a ferroelectric field effect transistor according to at least one embodiment. A graph 21 in FIG. 6 represents an example current flowing in the first channel 130a by a program pulse applied to a gate electrode, and a graph 22 represents an example current flowing in the second channel 130b by a program pulse applied to a gate electrode, and a graph 23 represents an example current flowing in the third channel 130c by a program pulse applied to a gate electrode. Furthermore, the rightest lines in the three graphs 21, 22, and 23 may represent voltage-current characteristics in an initial erase state, and by increasing the program pulse at certain intervals and applying the program pulse to the gate electrode, the voltage-current characteristics may move towards the left lines. For example, after applying a program pulse, a channel current may be measured by applying a read voltage, and after applying again an increased program pulse, the channel current may be measured by applying the read voltage. By repeating the foregoing, the graphs 21, 22, and 23 in FIG. 6 may be obtained.

Referring to FIG. 6, due to the work function difference of the first to third gate layers 142a, 142b, and 142c, a threshold voltage may be different in the first to third channels 130a, 130b, and 130c. Moreover, the threshold voltage may also vary according to an increase or decrease of the program pulse. Although the intensity of program pulse is increased at regular intervals, due to the polarization switching near the coercive voltage, the channel conductivity in each of the first to third channels 130a, 130b, and 130c may be changed slowly, and afterwards, drastically, and then slowly again. In other words, in each of the three graphs 21, 22, and 23, a distance between adjacent lines may increase at first and then narrow towards the left side from the right side.

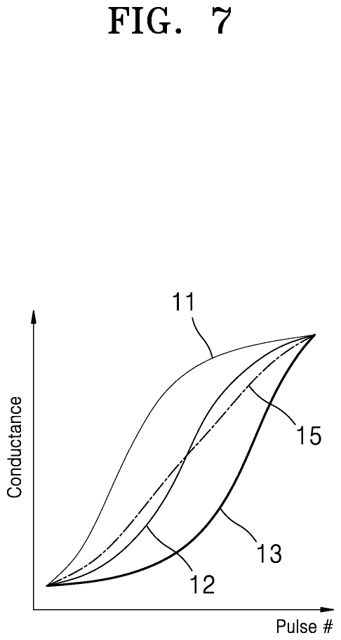

FIG. 7 shows a PD curve exhibiting a principle by which a ferroelectric field effect transistor has linear state change characteristics, according to at least one embodiment. When the first to third channels 130a, 130b, and 130c are driven by the same program pulse within a current range between the dashed horizontal lines in FIG. 6, the first PD curve 11 of the first channel 130a may change drastically at the initial stage, the third PD curve 13 of the third channel 130c may change drastically at the final stage, and the second PD curve 12 of the second channel 130b may change between the first PD curve 11 and the third PD curve 13. Accordingly, a non-linear conductivity change may be observed in each of the first to third channels 130a, 130b, and 130c. However, a composite PD curve 15, which is an average of the first to third PD curves 11, 12, and 13, may relatively show linear characteristics. Hence, the linear conductivity change characteristics may be achieved through the first to third channels 130a, 130b, and 130c connected in parallel.

As described above, the linear average conductivity change characteristics of the first to third channels 130a, 130b, and 130c may be due to the work function difference among the first to third gate layers 142a, 142b, and 142c respectively corresponding to the first to third channels 130a, 130b, and 130c. However, when the work function difference among the first to third gate layers 142a, 142b, and 142c is insignificant, the average conductivity change characteristics of the first to third channels 130a, 130b, and 130c may still be non-linear.

For example, the work function difference between the first gate layer 142a and the second gate layer 142b may be about 5% to about 100% of a smaller work function between the work function of the first gate layer 142a and the work function of the second gate layer 142b. The work function difference between the second gate layer 142b and the third gate layer 142c may be about 5% to about 100% of a smaller work function between the work function of the second gate layer 142b and the work function of the third gate layer 142c or the work function difference between the first gate layer 142a and the third gate layer 142c may be about 10% to about 100% of a smaller work function between the work function of the first gate layer 142a and the work function of the third gate layer 142c. Furthermore, a difference in gate voltage range for polarization switching among the first to third channels 130a, 130b, and 130c may be about 5% to about 20%.

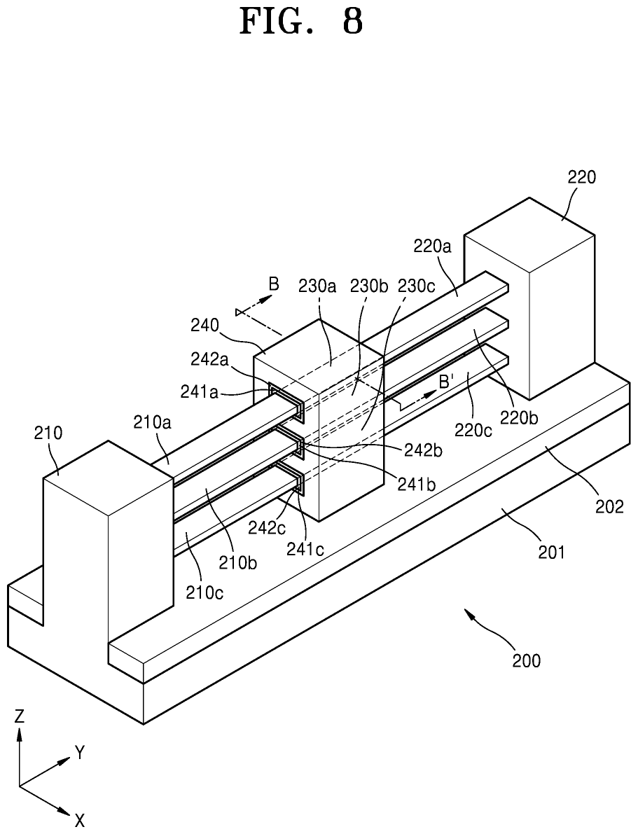

FIG. 8 is a perspective view schematically illustrating a structure of a ferroelectric field effect transistor according to at least one embodiment. Referring to FIG. 8, a ferroelectric field effect transistor 200 may include a substrate 201, a source 210 protruding from an upper surface of the substrate 201 in the Z direction, a drain 220 protruding from the upper surface of the substrate 201 in the Z direction, a first channel 230a having a shape of a bar extending in the Y direction, a second channel 230b having a shape of a bar extending in the Y direction, a third channel 230c having a shape of a bar extending in the Y direction, a first ferroelectric layer 241a surrounding the first channel 230a, a second ferroelectric layer 241b surrounding the second channel 230b, a third ferroelectric layer 241c surrounding the third channel 230c, a first gate layer 242a surrounding the first ferroelectric layer 241a, a second gate layer 242b surrounding the second ferroelectric layer 241b, a third gate layer 242c surrounding the third ferroelectric layer 241c, and a gate wiring 240 surrounding the first to third gate layers 242a, 242b, and 242c. The first channel 230a, the second channel 230b, and the third channel 230c may be spaced apart from the upper surface of the substrate 201 in the Z direction. Although FIG. 8 illustrates that the gate wiring 240 surrounds all of the first to third gate layers 242a, 242b, and 242c, the gate wiring 240 may include other and/or additional components electrically connecting the first to third gate layers 242a, 242b, and 242c to each other. The gate wiring 240 may form a gate electrode of the ferroelectric field effect transistor 200 together with the first to third gate layers 242a, 242b, and 2c.

The ferroelectric field effect transistor 200 may further include an isolator 202 for electrical isolation from another adjacent ferroelectric field effect transistor (not shown). The source 210 may include a first extension 210a, a second extension 210b, and a third extension 210c, which have the same bar shape as the first to third channels 230a, 230b, and 230c and extend in the Y direction to be connected to the first to third channels 230a, 230b, and 230c, respectively. The drain 220 may include a first extension 220a, a second extension 220b, and a third extension 220c, which have the same bar shape as the first to third channels 230a, 230b, and 230c and extend in the Y direction to be connected to the first to third channels 230a, 230b, and 230c, respectively.

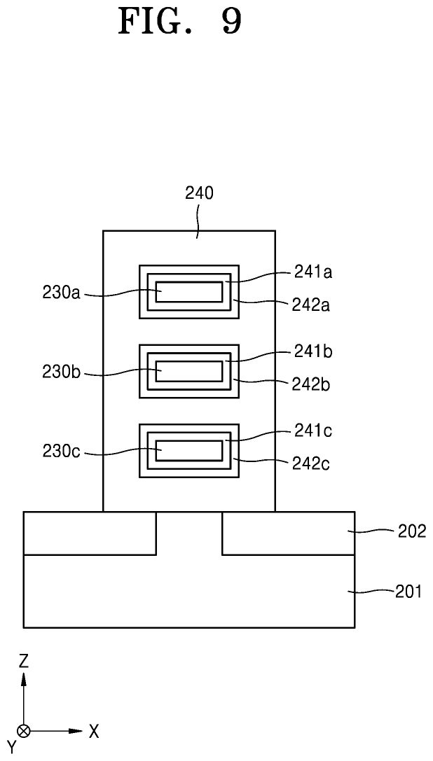

FIG. 9 is a cross-sectional view illustrating a channel and a gate structure of the ferroelectric field effect transistor 200 of FIG. 8, and in particular, FIG. 9 schematically illustrates a cross-section of the ferroelectric field effect transistor 200, taken along the line B-B′ of FIG. 8. Referring to FIG. 9, the gate wiring 240 may be disposed to protrude from an upper surface of the substrate 201 in the Z direction. The first to third channels 230a, 230b, and 230c may be spaced apart from each other in the Z direction. The first to third ferroelectric layers 241a, 241b, and 241c may have shapes of rings surrounding the first to third channels 230a, 230b, and 230c respectively corresponding to the first to third ferroelectric layers 241a, 241b, and 241c. The first to third gate layers 242a, 242b, and 242c may have shapes of rings respectively surrounding the first to third ferroelectric layers 241a, 241b, and 241c respectively corresponding to the first to third gate layers 242a, 242b, and 242c. The first to third gate layers 242a, 242b, and 242c may include metallic materials having different work functions.

Although FIGS. 8 and 9 illustrate that the first to third channels 230a, 230b, and 230c are spaced apart from each other in the Z direction, the first to third channels 230a, 230b, and 230c may be spaced apart from each other in the X direction. The ferroelectric field effect transistor 200 may be, for example, a Gate-All-Around FET (GAAFET) or a Multi Bridge Channel FET (MBCFET).

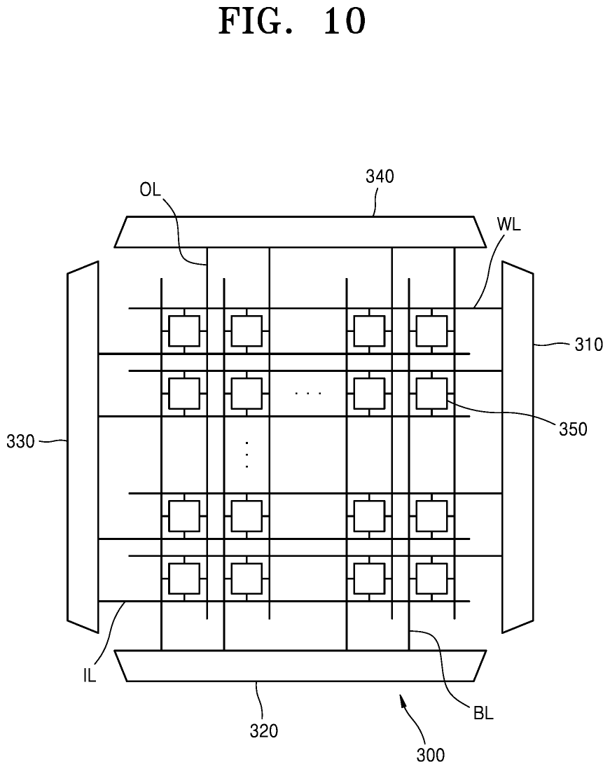

The aforementioned ferroelectric field effect transistor may be applied to a neural network apparatus and used to store information about connection strength (e.g., a weight) between neurons. For example, FIG. 10 is a block diagram schematically illustrating a configuration of a neural network apparatus according to at least one embodiment. Referring to FIG. 10, a neural network apparatus 300 may include a plurality of word lines WL, a plurality of bit lines BL, a plurality of input lines IL, a plurality of output lines OL, a plurality of synaptic elements 350, a word line driver 310 providing a signal to the plurality of word lines WL, a bit line driver 320 providing a signal to the plurality of bit lines BL, an input circuit 330 providing a signal to the plurality of input lines IL, and an output circuit 340 outputting a signal from the plurality of output lines OL. The output circuit 340 may include an Analog to Digital Converter (ADC) connected to each of the plurality of output lines OL. Although it is not shown in the drawings, the neural network apparatus 300 may further include general purpose components in addition to the components illustrated in FIG. 10. For example, the neural network apparatus 300 may include (and/or be connected to) processing circuitry, such hardware, software, or the combination of hardware and software, configured to control signals input into the neural network apparatus 300.

The plurality of word lines WL and the plurality of bit lines BL may be disposed to intersect with each other. The plurality of synaptic elements 350 may be disposed at intersection points where the plurality of word lines WL and the plurality of bit lines BL intersect with each other. Accordingly, the plurality of synaptic elements 350 may be disposed in a two-dimensional array. Although FIG. 10 illustrates that the plurality of input lines IL are disposed in parallel with the plurality of word lines WL, and the plurality of output lines OL are disposed in parallel with the plurality of bit lines BL, this is merely an example, and the extending direction of the plurality of input lines IL and the plurality of output lines OL is not limited thereto. Each of the plurality of synaptic elements 350 may be electrically connected to a word line of the plurality of word lines WL, a bit line of the plurality of bit lines BL, an input line, of the plurality of input lines IL, and an output line of the plurality of output lines OL, respectively.

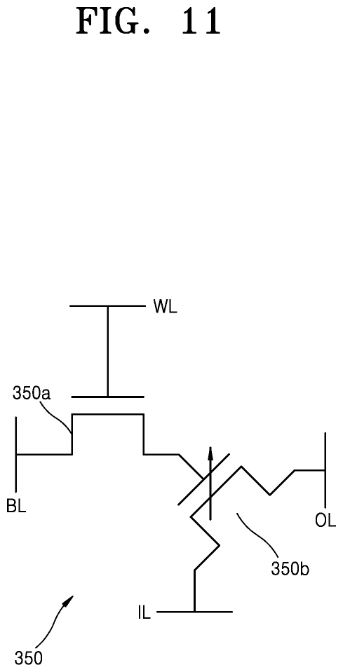

FIG. 11 is a schematic view of a unit synaptic element 350 of the neural network apparatus 300 of FIG. 10. Referring to FIG. 11, one unit synaptic element 350 may include an access transistor 350a and a ferroelectric field effect transistor 350b. The ferroelectric field effect transistor 350b may be at least one of the ferroelectric field effect transistors 100 or 200, described above. The access transistor 350a may function as a selection device turning on/off the synaptic element 350, and the ferroelectric field effect transistor 350b may function as a memory. A gate of the access transistor 350a may be electrically connected to a word line of the plurality of word lines WL, a source of the access transistor 350a may be electrically connected to a bit line of the plurality of bit lines BL, and a drain of the access transistor 350a may be connected to a gate of the ferroelectric field effect transistor 350b. A source of the ferroelectric field effect transistor 350b may be electrically connected to an input line of the plurality of input lines IL, and a drain of the ferroelectric field effect transistor 350b may be electrically connected to an output line of the plurality of output lines OL.

During a learning operation of the neural network apparatus 300, the access transistor 350a may be individually turned on through the corresponding word line WL, and a program pulse may be applied to the gate of the ferroelectric field effect transistor 350b through a bit line BL. Through an input line IL, a signal of learning data may be applied. Through such a process, a weight may be stored in each ferroelectric field effect transistor 350b. To this end, the word line driver 310 may be configured to sequentially apply a turn-on signal to the plurality of word lines WL during the learning operation of the neural network apparatus 300. The bit line driver 320 may be configured to apply a weight signal to the plurality of bit lines BL during the learning operation of the neural network apparatus 300.

During an inference operation of the neural network apparatus 300, all access transistors 350a may be turned on through all of the plurality of word lines WL, and a read voltage may be applied through the bit line BL. Then, currents from the synaptic elements 350 connected in parallel to the output lines OL may be aggregated and flow in each output line OL. The output circuit 340 may convert a current flowing in each of the plurality of word lines OL into a digital signal. To this end, the word line driver 310 may be configured to apply a turn-on signal to all of the plurality of word lines WL during the inference operation of the neural network apparatus 300. The bit line driver 320 may be configured to apply a read voltage to the plurality of bit lines BL during the inference operation of the neural network apparatus 300.

According to at least one embodiment, as the ferroelectric field effect transistor 350b has linear state change characteristics, in the synaptic element 350 of the neural network apparatus 300 a weight may be updated linearly. In other words, the weight or the synapse connection strength may be changed linearly in proportion to a program pulse provided through the bit lines BL.

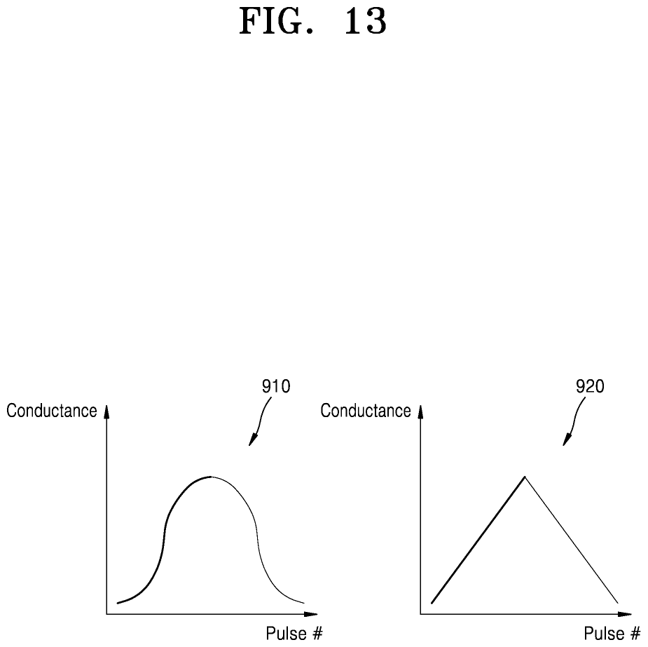

FIG. 13 is a view for comparing a PD characteristic curve of a single ferroelectric memory with a PD characteristic curve of a memory cell according to at least one embodiment.

Referring to FIG. 13, PD characteristic curves obtained by incremental step pulse programming (ISPP) for applying a voltage. A PD characteristic curve 910 represents PD characteristics of a single ferroelectric memory, and a PD characteristic curve 920 represents PD characteristics of a memory cell including a plurality of ferroelectric memories connected in parallel according to the present disclosure. The PD characteristic curve 910 represents bell-shaped long-term potentiation and depression (LTPD) characteristics, whereas the PD characteristic curve 920 represents linear LTPD characteristics.

In this way, the memory cell according to the present disclosure has linear characteristics with respect to voltage changes and thus, the synthesis conductance of the memory cell may be more precisely controlled. Further, as the synthesis conductance of the memory cell is precisely controlled, the distinctive steps of the weight corresponding to the synthesis conductance of the memory cell may be increased, and multi-value characteristics may be enhanced. When the multi-value characteristics are enhanced, a more elaborate neural network may be implemented.

As such, the linear change may provide more precise and/or accurate updates to the memory cells compared to memory cells including a single ferroelectric memory, which have nonlinear state-change characteristics.

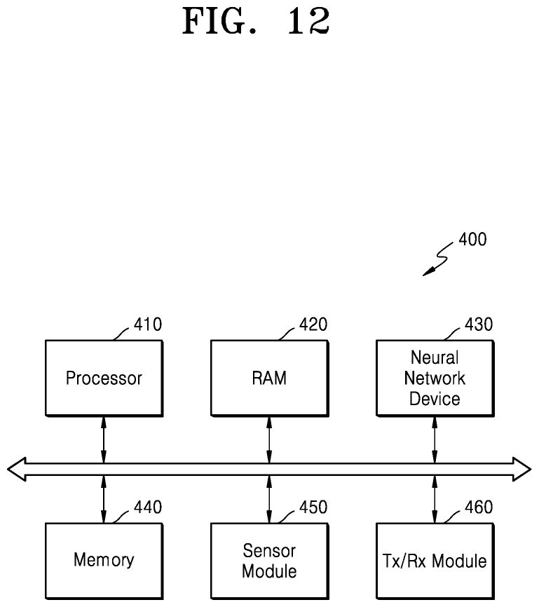

FIG. 12 is a block diagram schematically illustrating a configuration of an electronic device including a neural network apparatus. Referring to FIG. 12, an electronic device 400 may extract valid information by analyzing input data in real time, based on a neural network, estimate a situation based on the extracted information, or control components of devices mounted onto the electronic device 400. For example, the electronic device 400 may be applied to a robotic system, such as a drone, an Advanced Drivers Assistance System (ADAS), etc., a smart TV, a smartphone, a medical device, a mobile device, an image display device, a measurement device, an Internet of Things (IoT) device, etc., and may also be mounted onto at least one of various types of other devices.

The electronic device 400 may include a processor 410, random access memory (RAM) 420, a neural network apparatus 430, a memory 440, a sensor module 450, and a communication module 460. The electronic device 400 may further include an input/output module, a security module, a power controller, etc. Some of the hardware components of the electronic device 400 may be mounted on at least one semiconductor chip.

The processor 410 may control all operations of the electronic device 400. The processor 410 may include one processor core (i.e., a single core), or a plurality of processor cores (i.e., a multi-core). The processor 410 may process or execute programs and/or data stored in the memory 440. In some embodiments, the processor 410 may control functions of the neural network apparatus 430 by executing the programs stored in the memory 440. The processor 410 may be implemented as a Central Processing Unit (CPU), a Graphics Processing Unit (GPU), an Application Processor (AP), etc.

The RAM 420 may temporarily store programs, data, or instructions. For example, the programs and/or data stored in the memory 440 may be temporarily stored in the RAM 420, according to a control or booting code of the processor 410. The RAM 420 may be implemented as Dynamic RAM (DRAM), Static RAM (SRAM), etc.

The neural network apparatus 430 may perform operations of a neural network based on received input data, and generate an information signal based on a performance result. The neural network may include a Convolutional Neural Network CNN, a Recurrent Neural Network (RNN), a Feedforward Neural Network (FNN), a Long Short-Term Memory (LSTM), a Stacked Neural Network (SNN), a State-Space Dynamic Neural Network (SSDNN), a Deep Belief Network (DBN), a Restricted Boltzmann Machine (RBM), etc.; however, the present disclosure is not limited thereto. The neural network apparatus 430 may be a hardware accelerator for a neural network or a device including the hardware accelerator. The neural network apparatus 430 may perform not only operations of the neural network but also a read operation or a write operation.

The neural network apparatus 430 may correspond to the neural network apparatus 300 described with reference to FIGS. 10 and 11. As the neural network apparatus 430 is capable of implementing a weight having linear state change characteristics, the accuracy of operations of a neural network performed by the neural network apparatus 430 may increase, which leads to implementation of a more sophisticated neural network.

An information signal may include one of various types of recognition signals including a voice recognition signal, an object recognition signal, an image recognition signal, a biometrics recognition signal, etc. For example, the neural network apparatus 430 may receive as input data frame data included in a video stream, and generate, from the frame data, a recognition signal for an object included in an image represented by the frame data. However, the present disclosure is not limited thereto, and according to a type or a function of a device onto which the electronic device 400 is mounted, the neural network apparatus 430 may receive various types of input data and generate a recognition signal based on the input data.

The neural network apparatus 430 may perform, for example, linear regression, logistic regression, statistical clustering, Bayesian classification, decision trees, principal component analysis, a machine learning model including an expert system and/or an ensemble method, etc. Such a machine learning model may be used to provide various services, such as an image classification service, a user authentication service based on biometrics or biometric data, an ADAS, a voice assistant service, an Automatic Speech Recognition (ASR) service, etc.

The memory 440 may be a storage for storing data and may store an Operating System (OS), various programs, and various types of data. According to at least one embodiment, the memory 440 may store intermediate results generated in a process of performing operations of the neural network apparatus 430.

The memory 440 may be, for example, DRAM, but the present disclosure is not limited thereto. The memory 440 may include at least one of a volatile memory and a non-volatile memory. The non-volatile memory may include Read Only Memory (ROM), Programmable ROM (PROM), Electrically Programmable ROM (EPROM), Electrically Erasable and Programmable ROM (EEPROM), flash memory, Phase-change RAM (PRAM), Magnetic RAM (MRAM), Resistive RAM (RRAM), Ferroelectric RAM (FRAM), etc. The volatile memory may include DRAM, SRAM, Synchronous DRAM (SDRAM), PRAM, MRAM, RRAM, FRAM, etc. According to at least one embodiment, the memory 440 may include at least one of a Hard Disk Drive (HDD), a Solid State Drive (SSD), Compact Flash (CF) memory, a Secure Digital (SD) memory, a micro-Secure Digital (micro-SD) memory, a mini-Secure Digital (mini-SD) memory, a memory stick, etc.

The sensor module 450 may collect information around a device onto which the electronic device 400 is mounted. The sensor module 450 may sense and/or receive a signal (e.g., an image signal, a voice signal, a magnetic signal, a biometric signal, a touch signal, etc.) from the outside of the electronic device 400 and convert the sensed or received signal into data. To this end, the sensor module 450 may include at least one of various types of sensing devices, such as a microphone, an imaging device, an image sensor, a Light Detection And Ranging (LiDAR) sensor, an ultrasonic sensor, an infrared sensor, a biosensor, a touch sensor, etc.

The sensor module 450 may provide the data to the neural network apparatus 430 as input data. For example, the sensor module 450 may include an image sensor, generate a video stream by photographing an external environment of the electronic device 400, and sequentially provide consecutive data frames of the video stream to the neural network apparatus 430 as input data. However, the present disclosure is not limited thereto, and the sensor module 450 may provide various types of data to the neural network apparatus 430.

The communication module 460 may include various wired or wireless interfaces capable of communicating with external devices. For example, the communication module 460 may include a wired Local Area Network (LAN), a Wireless Local Area Network (WLAN), such as wireless fidelity (Wi-Fi), a Wireless Personal Area Network (WPAN), such as Bluetooth, a wireless Universal Serial Bus (USB), Zigbee, Near Field Communication (NFC), Radio-Frequency Identification (RFID), Power Line Communication (PLC), a communication interface accessible to, e.g., 3rd Generation (3G), 4th Generation (4G), 5th Generation (5G), or Long Term Evolution (LTE) mobile cellular networks, and/or the like.

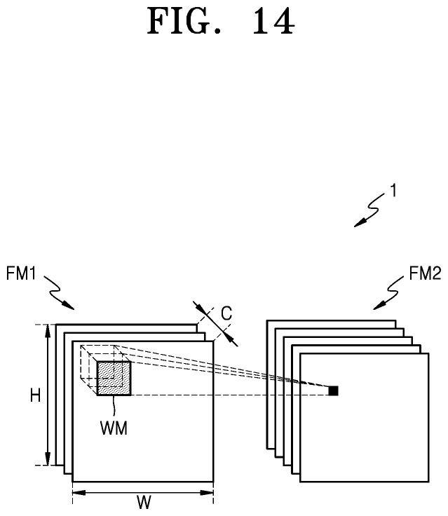

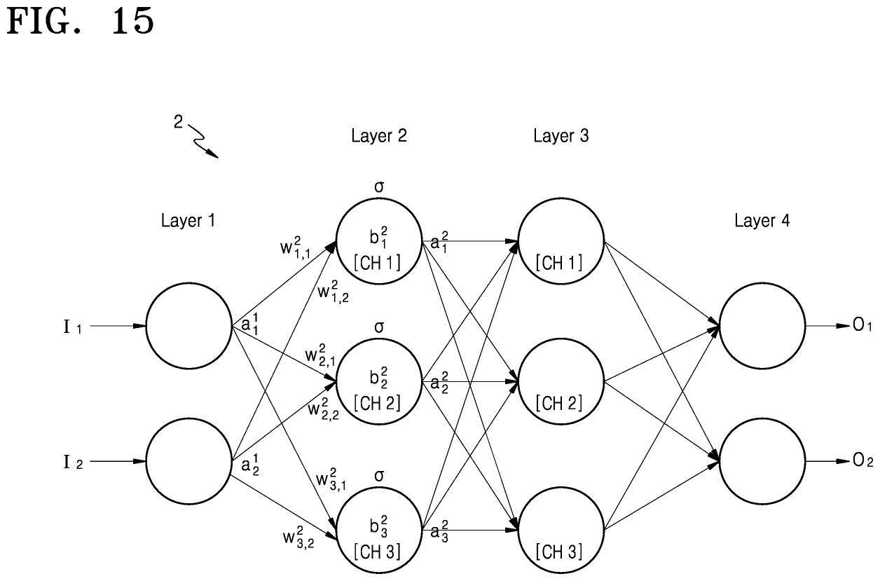

FIG. 14 is a view for describing an architecture of a neural network according to at least one embodiment. FIG. 15 is a view for describing an arithmetic operation performed in a neural network according to at least one embodiment.

Referring to FIG. 14, a neural network 1 may be expressed as a model using nodes and edges. The model may be, for example, a mathematic model, a digital model, an analog model, and/or a combination thereof. The neural network 1 may be an architecture of a deep neural network (DNN) and/or n-layers neural networks. The DNN and/or n-layers neural networks may correspond to convolutional neural networks (CNN), recurrent neural networks (RNN), deep belief networks, restricted Boltzmann machines, and/or the like. For example, the neural network 1 may be implemented with the convolutional neural networks (CNN). However, the example embodiments are not limited thereto. The neural network 1 of FIG. 1 may correspond to some layers of the CNN. Thus, the neural network 1 may correspond to a convolution layer, a pooling layer, a fully connected layer, and/or the like of the CNN. Hereinafter, for convenience, the description of the neural network 1 corresponds to the convolution layer of the CNN.

In the convolution layer, a first feature map FM1 may correspond to an input feature map, and the second feature map FM2 may correspond to an output feature map. The feature map may mean and/or represent a data set in which various features of input data are expressed. The first and second feature maps FM1 and FM2 may be a high-dimensional matrix of two or more dimensions and have respective activation parameters. The feature maps FM1 and FM2 may correspond to three-dimensional feature maps (for example, the feature maps FM1 and FM2 may have a width W (or referred to as a column), a height (or referred to as a row), and a depth C). In these cases, the depth C may correspond to the number of channels in the corresponding feature map.

In the convolution layer, a convolution operation may be performed on the first feature map FM1 and a weight map WM. As a result, the second feature map FM2 may be generated. The weight map WM may filter the first feature map FM1 and may also be referred to as a weight filter and/or weight kernel. In an example, the depth of the weight map WM (e.g., the number of channels of the weight map WM) may be the same as the depth of the first feature map FM1 (e.g., the number of channels of the first feature map FM1). The weight map WM may be shifted to transverse the first feature map FM1 as a sliding window. During each shift, each of weights included in the weight map WM may be multiplied and added to all feature values in an area overlapping the first feature map FM1. As the first feature map FM1 and the weight map WM are convoluted, one channel of the second feature map FM2 may be generated.

Although one weight map WM is indicated in FIG. 1, substantially, a plurality of weight maps may be convoluted with the first feature map FM1 so that a plurality of channels of the second feature map FM2 may be generated. The second feature map FM2 of the convolution layer may be an input feature map of a next layer. For example, the second feature map FM2 may be an input feature map of a pooling layer. However, the example embodiments are not limited thereto.

FIG. 15 is a view for describing an arithmetic operation performed in a neural network according to at least one embodiment.

Referring to FIG. 15, a neural network 2 may have a structure including an input layer, hidden layers, and an output layer, which may perform an arithmetic operation based on received input data (for example, I₁ and I₂) and may generate output data (for example, O₁ and O₂) based on the result of performing the arithmetic operation.

In some example embodiments, the neural network 2 may be a DNN and/or n-layers neural networks including two or more hidden layers, as described above. For example, as shown in FIG. 15, the neural network 2 may be a DNN including an input layer Layer 1, two (or more) hidden layers Layer 2 and Layer 3, and an output layer Layer 4. When the neural network 2 is implemented with a DNN architecture, the neural network 2 may include more layers configured to (and/or capable of) processing valid information. Thus, the neural network 2 may process more complicated data sets than a neural network having a single layer. Also, although the neural network 2 includes four layers, this is just an example, and the neural network 2 may include less or more layers and/or less or more channels. That is, the neural network 2 may include layers having various structures different from those shown in FIG. 2.

Each of the layers included in the neural network 2 may include a plurality of channels. The plurality of channels may correspond to a plurality of artificial nodes, known as neurons, processing elements (PEs), units, and/or similar terms. For example, as shown in FIG. 15, Layer 1 may include two channels (nodes), and each of Layer 2 and Layer 3 may include three channels. Also, this is just an example, and each of the layers included in the neural network 2 may include different numbers of channels (nodes).

The channels included in each of the layers of the neural network 2 may be connected to one another to process data. For example, one channel may receive data from other channels to perform an arithmetic operation and/or to output the result of the arithmetic operation to other channels.

Each of an input and an output of each of the channels may be referred to, respectively, as an input activation and an output activation. For example, the activation may be an output of one channel and/or, a parameter corresponding to an input of channels included in the next layer. Also, each of the channels may determine its own activation based on activations received from channels included in the previous layer and weights. The weight may represent a parameter used to calculate an output activation at each channel may be a value allocated to a connection relationship between the channels.

Each of the channels may be processed by a computational unit and/or processing element for outputting an output activation by receiving an input, and an input-output of each of the channels may be mapped. For example, when σ is an activation function, wⱼₖⁱ is a weight from a k-tph channel included in an (i−1)-th layer to a j-th channel included in an i-th layer, bⱼⁱ is a bias of the j-th channel included in the i-th layer and aⱼⁱ is an activation of the j-th channel included in the i-th layer, the activation aⱼⁱ may be calculated using equation 1 below.

$${a}_{j}^{i} = σ ( {\sum }_{k} ( {w}_{jk}^{i} \times {a}_{k}^{i - 1} ) + {b}_{j}^{i} ) \qquad [ Equation 1 ]$$

As shown in FIG. 2, an activation of a first channel CH1 of a second layer Layer 2 may be expressed as a₁². Accordingly, a₁² may have a value of a₁²=σ(w_{1,1}²×a₁¹+w_{1,2}²×a₂¹+b₁²) according to equation 1. The activation function σ may be a rectified linear unit (ReLU). However, embodiments are not limited thereto. For example, the activation function σ may be Sigmoid, hyperbolic tangent tanh, Maxout, and/or the like.

As described above, in the neural network 2, numerous data sets may be exchanged between a plurality of channels interconnected, and an arithmetic operation process may be performed while passing through layers. In the computation process, numerous multiply-accumulate (MAC) operations may be performed, and numerous memory access operations for loading an activation and a weight to be calculated of the MAC operation at an appropriate time need to be performed together.

Also, in a general digital computer, a computational unit and memory are separated from each other, and a Von Neumann structure including a common data bus for data transmission between two separated blocks may be used. Thus, in the process of implementing the neural network 2 in which data movement and operations are continuously repeated, a lot of time may be required for data transmission, and excessive power may be consumed. In order to solve these problems, an in-memory computing circuit has been provided above.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A ferroelectric field effect transistor comprising:
a source;
a drain;
a first channel connected to and between the source and the drain;
a second channel connected to and between the source and the drain and spaced apart from the first channel;
a ferroelectric layer at least partially covering the first channel and the second channel;
a first gate layer on the ferroelectric layer, the first gate layer at least partially covering the first channel;
a second gate layer on the ferroelectric layer, the second gate layer at least partially covering the second channel; and
a gate wiring electrically connected to the first gate layer and the second gate layer,
wherein the first gate layer includes a first metallic material having a first work function, the second gate layer includes a second metallic material having a second work function, and the second work function is different from the first work function.

2. The ferroelectric field effect transistor of claim 1, wherein the first channel and the second channel are electrically connected in parallel.

3. The ferroelectric field effect transistor of claim 1, wherein at least one of the first metallic material or the second metallic material includes at least one of TiN, TiAlN, TaN, Co, WN, NbN, W, Mo, or Pt.

4. The ferroelectric field effect transistor of claim 1, wherein the ferroelectric layer includes an oxide and a dopant,
wherein the oxide includes at least one of Si, Al, Hf, or Zr, and
the dopant is at least one of Si, Al, Y, La, Gd, Mg, Ca, Sr, Ba, Ti, Zr, Hf, N, MgZnO, AlScN, BaTiO₃, Pb(Zr,Ti)O₃, SrBiTaO₇, or polyvinylidene fluoride (PVDF).

5. The ferroelectric field effect transistor of claim 1 further comprising:
a substrate,
wherein the source, the drain, the first channel, and the second channel are protruded from an upper surface of the substrate in a first direction.

6. The ferroelectric field effect transistor of claim 5, wherein the first channel and the second channel extend in a second direction perpendicular to the first direction.

7. The ferroelectric field effect transistor of claim 6, wherein the first channel and the second channel are spaced apart from each other in a third direction perpendicular to the first direction and the second direction.

8. The ferroelectric field effect transistor of claim 1, further comprising:
a substrate,
wherein the source and the drain protrude from an upper surface of the substrate in a first direction, and
the first channel and the second channel are spaced apart from the upper surface of the substrate in the first direction.

9. The ferroelectric field effect transistor of claim 8, wherein
the first channel and the second channel extend in a second direction perpendicular to the first direction, and
the first channel and the second channel are spaced apart from each other in at least one of the first direction or in a third direction perpendicular to the first direction and the second direction.

10. The ferroelectric field effect transistor of claim 8, wherein the ferroelectric layer includes a first ferroelectric layer surrounding the first channel and a second ferroelectric layer surrounding the second channel.

11. The ferroelectric field effect transistor of claim 10, wherein the first gate layer surrounds the first ferroelectric layer, and the second gate layer surrounds the second ferroelectric layer.

12. The ferroelectric field effect transistor of claim 1, further comprising:
a third channel spaced apart from the first channel and the second channel; and
a third gate layer on the ferroelectric layer, the third gate layer at least partially covering the third channel and including a third metallic material having a third work function, the third work function different from the first work function and the second work function,
wherein the gate wiring electrically connects the first gate layer, the second gate layer, and the third gate layer to each other.

13. The ferroelectric field effect transistor of claim 1, wherein a value obtained by dividing a greater work function, between the first work function of the first gate layer and the second work function of the second gate layer, by the other work function of the first gate layer or the second gate layer, is between 5% to 100%.

14. A neural network apparatus comprising:
a plurality of word lines;
a plurality of bit lines;
a plurality of input lines;
a plurality of output lines; and
a plurality of synaptic elements at intersection points where the plurality of word lines and the plurality of bit lines intersect with each other, and electrically connecting a corresponding word line of the plurality of word lines, a corresponding bit line of the plurality of bit lines, a corresponding input line of the plurality of input lines, and a corresponding output line of the plurality of output lines,
wherein each of the plurality of synaptic elements includes an access transistor and a ferroelectric field effect transistor,
wherein the ferroelectric field effect transistor includes
a source,
a drain,
a first channel connected to and between the source and the drain,
a second channel connected to and between the source and the drain and spaced apart from the first channel,
a ferroelectric layer at least partially covering the first channel and the second channel,
a first gate layer on the ferroelectric layer, the first gate layer at least partially covering the first channel,
a second gate layer on the ferroelectric layer, the second gate layer at least partially covering the second channel, and
a gate wiring electrically connecting the first gate layer to the second gate layer,
wherein the first gate layer includes a first metallic material having a first work function, the second gate layer includes a second metallic material having a second work function, and the second work function is different from the first work function.

15. The neural network apparatus of claim 14, wherein the ferroelectric field effect transistor further includes:
a third channel spaced apart from the first channel and the second channel; and
a third gate layer on the ferroelectric layer, the third gate layer at least partially covering the third channel and including a third metallic material having a third work function, the third work function different from the first work function and the second work function,
wherein the gate wiring electrically connects the first gate layer, the second gate layer, and the third gate layer to each other.

16. The neural network apparatus of claim 14, wherein, for each of the plurality of synaptic elements,
a gate of the access transistor is electrically connected to the corresponding word line,
a source of the access transistor is electrically connected to the corresponding bit line,
a drain of the access transistor is electrically connected to the gate wiring of the ferroelectric field effect transistor,
the source of the ferroelectric field effect transistor is electrically connected to the corresponding input line, and
the drain of the ferroelectric field effect transistor is electrically connected to the corresponding output line.

17. The neural network apparatus of claim 14, further comprising:
a word line driver configured to provide a word line signal to the plurality of word lines;
a bit line driver configured to provide a bit line signal to the plurality of bit lines;
an input circuit configured to provide an input signal to the plurality of input lines; and
an output circuit configured to output an output signal received from the plurality of output lines.

18. The neural network apparatus of claim 17, wherein, during a learning operation of the neural network apparatus, the word line driver is configured to sequentially apply a turn-on signal to the plurality of word lines, and the bit line driver is configured to apply a weight signal to the plurality of bit lines.

19. The neural network apparatus of claim 18, wherein, during an inference operation of the neural network apparatus, the word line driver is configured to apply the turn-on signal to the plurality of word lines, and the bit line driver is configured to apply a read voltage to the plurality of bit lines.

20. An electronic device comprising:
the neural network apparatus according to claim 14;
a memory including computer-executable instructions; and
a processor configured to control functions of the neural network apparatus by executing the computer-executable instructions stored in the memory such that the neural network apparatus performs a neural network operation based on input data received from the processor and generates an information signal corresponding to the input data, based on a result of the neural network operation.
